(19) United States
(12) Patent Application Publication
(10) Pub. No.: US 2025/0201624 A1
(43) Pub. Date: Jun. 19, 2025

(54) SEMICONDUCTOR DEVICE AND METHOD OF MANUFACTURING THE SAME

(71) Applicant: NANYA TECHNOLOGY CORPORATION, New Taipei City (TW)

(72) Inventors: Ming-Yang HSIEH, Taoyuan City (TW); Ying-Cheng CHUANG, Taoyuan City (TW)

(21) Appl. No.: 18/539,298

(22) Filed: Dec. 14, 2023

(51) Int. Cl. H01L 21/762; H01L 21/02; H01L 21/308

(52) U.S. Cl. CPC H01L 21/76224; H01L 21/02271; H01L 21/02282; H01L 21/02318; H01L 21/308

(57) ABSTRACT

The present disclosure provides a method of manufacturing a semiconductor device. The method includes: forming a patterned hardmask layer on a substrate in a periphery area and an array area of the substrate, in which the patterned hardmask layer has a plurality of hollowed portions; forming a plurality of trenches on the substrate in the periphery area and the array area through the hollowed portions of the patterned hardmask layer; depositing a first oxide layer on inner surfaces of the trenches by a first deposition process; and depositing a second oxide layer on the first oxide layer by a second deposition process, so that the trenches are filled, in which a material of the first oxide layer and a material of the second oxide layer are identical.

### BACKGROUND

### Field of Invention

The present invention relates to a semiconductor device and a method of manufacturing the same.

### Description of Related Art

With the evolution of generations of semiconductor processes, there will be challenges of trench filling process. For example, one of the related challenges brought by the semiconductor device is that defects may occur during the process of filling the trench if the trench is not filled in a proper manner. The defects are likely to cause resistance variation and a decrease in the breakdown voltage in subsequent related processes (for example, forming contact string (CS) and word line (WL) in the filling material), thereby reducing the performance of the entire semiconductor device.

### SUMMARY

In view of this, one purpose of the present disclosure is to provide a semiconductor device and a method of manufacturing the same that can solve the aforementioned problems.

In order to achieve the above objective, according to an embodiment of the present disclosure, a method of manufacturing a semiconductor device includes: forming a patterned hardmask layer on a surface of a substrate in a periphery area and an array area of the substrate, in which the patterned hardmask layer has a plurality of hollowed portions; forming a plurality of trenches on the surface of the substrate in the periphery area and the array area through the hollowed portions of the patterned hardmask layer; depositing a first oxide layer on inner surfaces of the trenches by a first deposition process, in which the first deposition process is performed by flowable chemical vapor deposition; and depositing a second oxide layer on the first oxide layer by a second deposition process, so that the trenches are filled, in which a material of the first oxide layer and a material of the second oxide layer are identical, in which the second deposition process is performed by spin-on dielectric coating deposition.

In one or more embodiments of the present disclosure, the first deposition process is performed such that the first oxide layer fully fills the trenches in the array area.

In one or more embodiments of the present disclosure, the first deposition process is performed such that the first oxide layer fully fills the trenches in the array area but does not fully fill the trenches in the periphery area due to the trenches in the array area and the periphery area having different aspect ratios.

In one or more embodiments of the present disclosure, the first oxide layer and the second oxide layer fully fill the trenches in the periphery area.

In one or more embodiments of the present disclosure, the depositing the second oxide layer is performed after the depositing the first oxide layer.

In one or more embodiments of the present disclosure, the method further includes annealing the first oxide layer after the depositing the first oxide layer.

In one or more embodiments of the present disclosure, the method further includes densifying the second oxide layer after the depositing the second oxide layer.

In one or more embodiments of the present disclosure, a process temperature of the densifying the second oxide layer is lower than a process temperature of the annealing the first oxide layer.

In one or more embodiments of the present disclosure, the densifying the second oxide layer is performed by an annealing process.

In one or more embodiments of the present disclosure, the method further includes removing portions of the first oxide layer and the second oxide layer by a planarization process.

In one or more embodiments of the present disclosure, the removing portions of the first oxide layer and the second oxide layer makes remaining portions of the first oxide layer and the second oxide layer be co-planar with the patterned hardmask layer.

In one or more embodiments of the present disclosure, the removing portions of the first oxide layer and the second oxide layer is performed after the densifying the second oxide layer.

In one or more embodiments of the present disclosure, the method further includes annealing the first oxide layer and the second oxide layer after the depositing the second oxide layer.

According to an embodiment of the present disclosure, a semiconductor device includes a substrate, a first oxide layer, a second oxide layer. The substrate has a plurality of trenches in a periphery area and an array area of the substrate. An aspect ratio of a width to a depth of the trenches in the periphery area is in a range from 1.25 to 1.5. The first oxide layer is disposed on inner surfaces of the trenches of the substrate. The second oxide layer is disposed on the first oxide layer, so that the trenches are filled. A material of the first oxide layer and a material of the second oxide layer are identical. An aspect ratio of the trenches in the array area and the aspect ratio of the trenches in the periphery area are different.

In one or more embodiments of the present disclosure, the first oxide layer fully fills the trenches in the array area.

In one or more embodiments of the present disclosure, the first oxide layer fully fills the trenches in the array area but does not fill the trenches in the periphery area.

In one or more embodiments of the present disclosure, the first oxide layer and the second oxide layer fully fills the trenches in the periphery area.

In one or more embodiments of the present disclosure, an aspect ratio of a width to a depth of the trenches in the array area is less than the aspect ratio of the width to the depth of the trenches in the periphery area.

In summary, in the semiconductor device and the method of manufacturing the same of the present disclosure, since the step of deposition to fill the trenches with different aspect ratios are split into plural steps, the difficulty of the quality control of the filled material can be lowered down. In the semiconductor device and the method of manufacturing the same of the present disclosure, since the first deposition process is performed by flowable chemical vapor deposition, the trenches in the array area can be fully filled in a proper manner, thereby reducing the probability of generating defects in the dielectric layer, and further prevent the filled dielectric layer from occurring short problem in subsequent process. In the semiconductor device and the method of manufacturing the same of the present disclosure, since the second deposition process is performed by spin-on dielectric coating deposition, since the annealing temperature of the second oxide layer formed by spin-on dielectric coating deposition is relatively low, so that the second deposition process can prevent the problem of the array island structure falling, thereby improving overall electrical performance (for example, in-die overlay performance).

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart of a method of manufacturing a semiconductor device in accordance with an embodiment of the present disclosure;

FIG. 2 is a cross-sectional view of an intermediate stage of manufacturing a semiconductor device in accordance with an embodiment of the present disclosure;

FIG. 3 is a cross-sectional view of an intermediate stage of manufacturing the semiconductor device in accordance with an embodiment of the present disclosure;

FIG. 4 is a cross-sectional view of an intermediate stage of manufacturing the semiconductor device in accordance with an embodiment of the present disclosure;

FIG. 5 is a cross-sectional view of an intermediate stage of manufacturing the semiconductor device in accordance with an embodiment of the present disclosure;

FIG. 6 is a cross-sectional view of an intermediate stage of manufacturing the semiconductor device in accordance with an embodiment of the present disclosure; and

FIG. 7 is a cross-sectional view of an intermediate stage of manufacturing the semiconductor device in accordance with another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

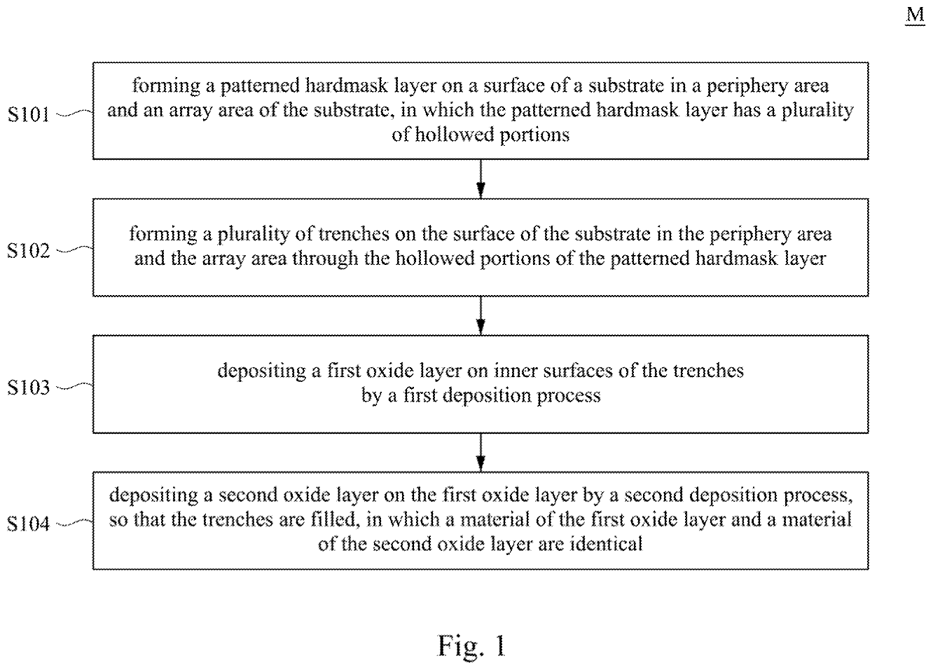

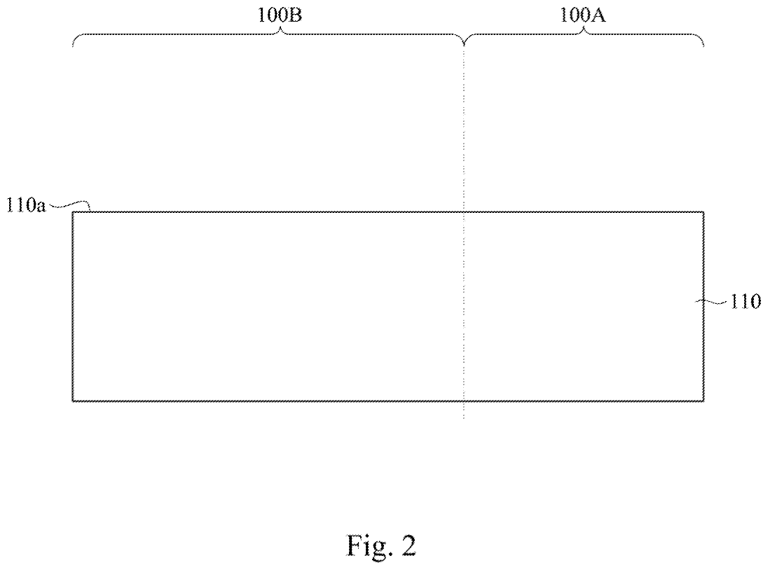

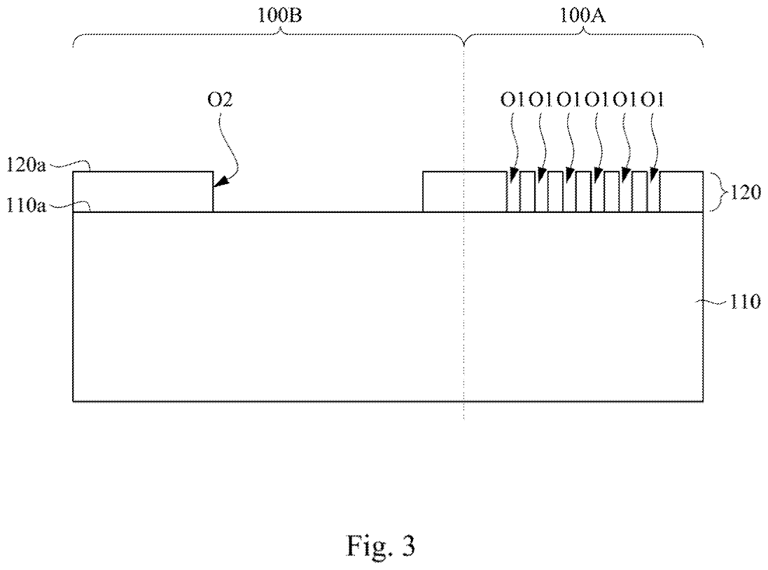

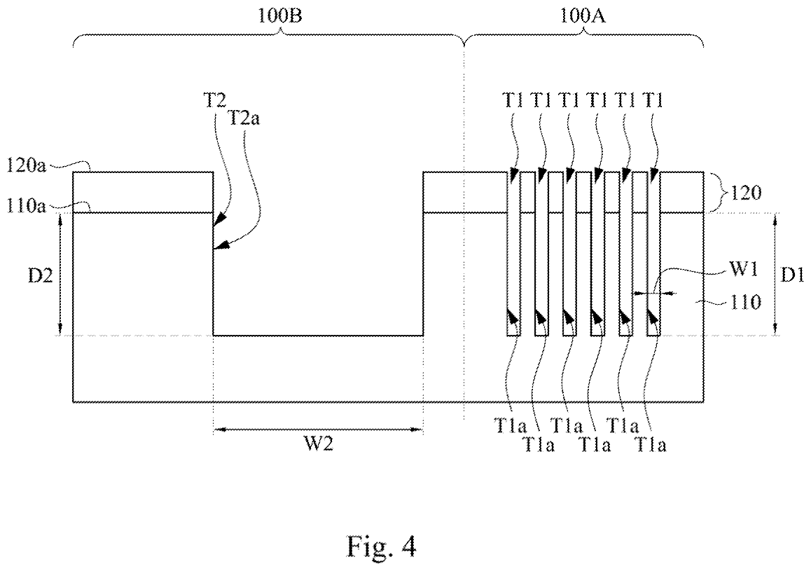

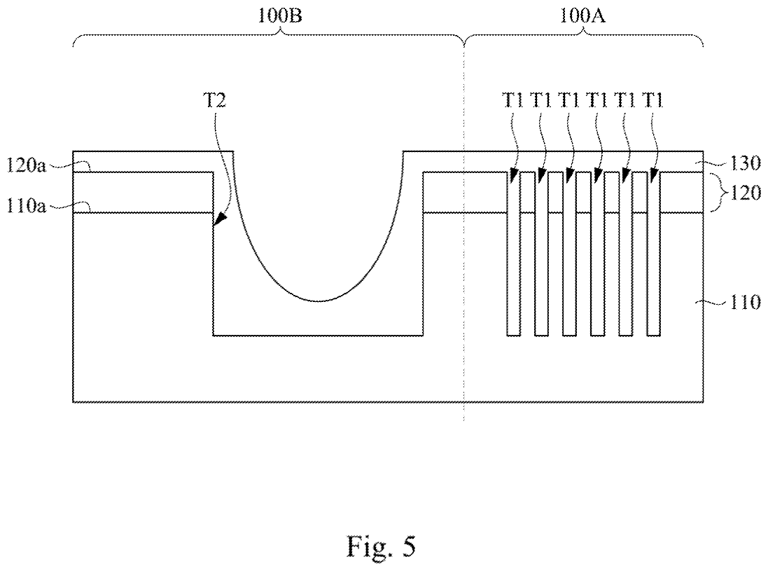

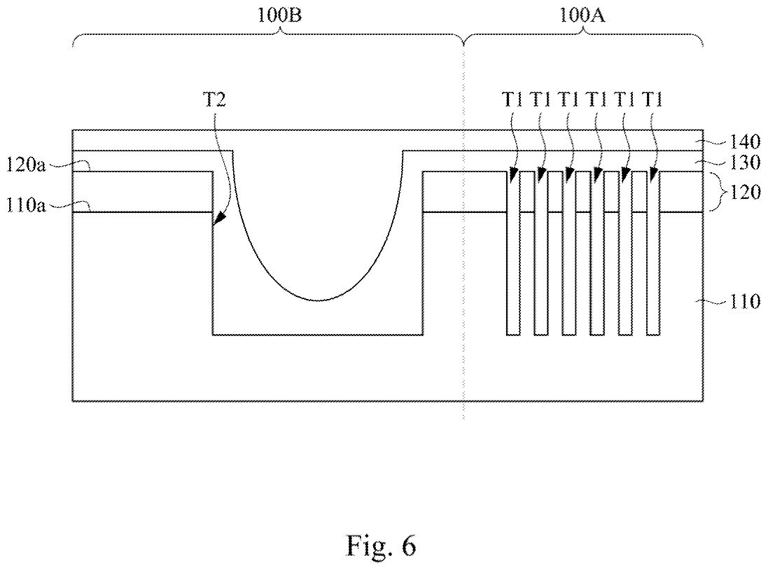

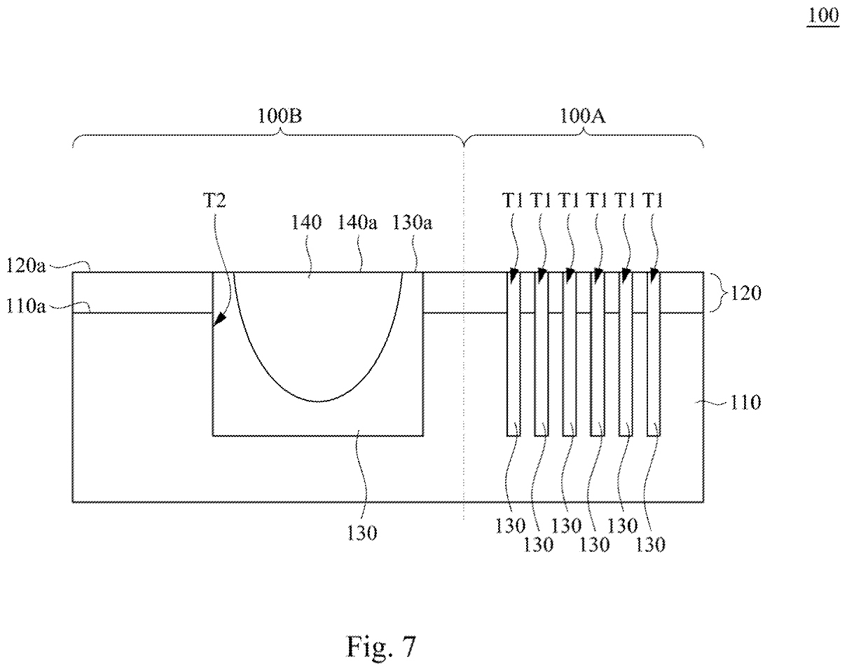

Reference is made to FIG. 1. FIG. 1 is a flow chart of a method M of manufacturing a semiconductor device 100 as shown in FIG. 7 in accordance with an embodiment of the present disclosure. The method M shown in FIG. 1 includes a step S101, a step S102, a step S103, and a step S104. Please refer to FIG. 1, FIG. 2, and FIG. 3 for better understanding the step S101, refer to FIG. 1, and FIG. 4 for better understanding the step S102, refer to FIG. 1, and FIG. 5 for better understanding the step S103, and refer to FIG. 1, FIG. 6, and FIG. 7 for better understanding the step S104.

Step S101, step S102, step S103, and step S104 are described in detail below.

Step S101: forming a patterned hardmask layer on a surface of a substrate in a periphery area and an array area of the substrate, in which the patterned hardmask layer has a plurality of hollowed portions.

Reference is made to FIG. 2. FIG. 2 is a cross-sectional view of an intermediate stage of manufacturing a semiconductor device 100 in accordance with an embodiment of the present disclosure. In step S101, a patterned hardmask layer 120 is formed on a surface 110a of a substrate 110 in an array area 100A and a periphery area 100B of the substrate 110, wherein the patterned hardmask layer 120 has a plurality of hollowed portions O1 and hollowed portions O2. As shown in FIG. 2, a substrate 110 is provided. As shown in FIG. 2, a substrate 110 includes the array area 100A and the periphery area 100B.

In some embodiments, the substrate 110 may be silicon-based substrate. In some embodiments, the substrate 110 may include a material, such as monocrystalline silicon, polysilicon, amorphous silicon, or the like. However, any suitable material may be utilized.

In some embodiments, the substrate 110 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the substrate 110.

Reference is made to FIG. 3. FIG. 3 is a cross-sectional view of an intermediate stage of manufacturing the semiconductor device 100 in accordance with an embodiment of the present disclosure. As shown in FIG. 3, the patterned hardmask layer 120 is disposed on the substrate 110. As shown in FIG. 3, the patterned hardmask layer 120 has the plurality of hollowed portions O1 and hollowed portions O2. The hollowed portions O1 are located in the array area 100A, whereas the hollowed portions O2 are located in the periphery area 100B. To simplify the description, the hollowed portions O2 are depicted as a singular hollowed portion in FIG. 3.

In some embodiments, the hollowed portions O1 and the hollowed portions O2 may be formed by any suitable method, for example, wet etching, dry etching, or the like. The present disclosure is not intended to limit the methods of forming the hollowed portions O1 and the hollowed portions O2.

In some embodiments, a width of each of the hollowed portions O2 is greater than a width of each of the hollowed portions O1.

In some embodiments, the patterned hardmask layer 120 may include a material, such as silicon nitride (SiₓN_{y}), titanium nitride (TiₓN_{y}), or the like. However, any suitable material may be utilized.

Step S102: forming a plurality of trenches on the surface of the substrate in the periphery area and the array area through the hollowed portions of the patterned hardmask layer.

Reference is made to FIG. 4. FIG. 4 is a cross-sectional view of an intermediate stage of manufacturing the semiconductor device 100 in accordance with an embodiment of the present disclosure. In step S102, a plurality of trenches T1 and trenches T2 are formed on the surface 110a of the substrate 110 the array area 100A and in the periphery area 100B through the hollowed portions O1 and the hollowed portions O2 of the patterned hardmask layer 120. As shown in FIG. 4, the trenches T1 and the trenches T2 are respectively formed through the hollowed portions O1 and the hollowed portions O2 of the patterned hardmask layer 120. In some embodiments, the trenches T1 and the trenches T2 are recessed from the surface 110a of the substrate 110.

As shown in FIG. 4, each of the trenches T1 includes a depth D1 and a width W1. In some embodiments, the depth D1 may be larger than the width W1, but the present disclosure is not limited thereto.

As shown in FIG. 4, each of the trenches T2 includes a depth D2 and a width W2. In some embodiments, an aspect ratio of the width W2 to the depth D2 of the trench T is in a range from about 1.25 to about 1.5, but the present disclosure is not limited thereto. In some embodiments, the depth D2 may be less than the width W2, but the present disclosure is not limited thereto.

In some embodiments, an aspect ratio of the width W1 to the depth D1 of each of the trenches T1 in the array area 100A is less than the aspect ratio of the width W2 to the depth D2 of each of the trenches T2 in the periphery area 100B.

In some embodiments, the trenches T1 and the trenches T2 may be formed by any suitable method, for example, wet etching, dry etching, or the like. The present disclosure is not intended to limit the methods of forming the trenches T1 and the trenches T2.

Step S103: depositing a first oxide layer on inner surfaces of the trenches by a first deposition process.

Reference is made to FIG. 1 and FIG. 5. FIG. 5 is a cross-sectional view of an intermediate stage of manufacturing a semiconductor device 100 in accordance with an embodiment of the present disclosure. In step S103, a first oxide layer 130 is deposited on an inner surface Tla of each of the trenches T1 and an inner surface T2a of each of the trenches T2 of the substrate 110. As shown in FIG. 5, the first oxide layer 130 is formed on a surface 120a of the patterned hardmask layer 120 after step S102. Specifically, the first oxide layer 130 is at least filled in the trenches T1 in the array area 100A. In some embodiments, the trenches T1 are fully filled by the first oxide layer 130. In some embodiments, the first oxide layer 130 fully fills the trenches T1 in the array area 100A but does not fill the trenches T2 in the periphery area 100B.

In some embodiments, the first oxide layer 130 may include a material, such as oxide. For example, the material may include silicon oxide (SiO₂) or the like. The present disclosure is not intended to limit the material of the first oxide layer 130.

In some embodiments, the first oxide layer 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the first oxide layer 130.

In some embodiments, the first oxide layer 130 may be deposited by a flowable chemical vapor deposition (FCVD) process.

Step S104: depositing a second oxide layer on the first oxide layer by a second deposition process, so that the trenches are filled.

Reference is made to FIG. 1 and FIG. 6. FIG. 6 is a cross-sectional view of an intermediate stage of manufacturing a semiconductor device 100 in accordance with an embodiment of the present disclosure. In step S104, a second oxide layer 140 is deposited on the first oxide layer 130 by the second deposition process. As shown in FIG. 6, the second oxide layer 140 is formed on the first oxide layer 130 after step S103. Specifically, the second oxide layer 140 is filled in the trenches T2 in the periphery area 100B. In some embodiments, the trenches T2 are filled by the second oxide layer 140. In some embodiments, the second oxide layer 140 fully fills the trenches T2 in the periphery area 100B but does not fill the trenches T1 in the array area 100A.

In some embodiments, the second oxide layer 140 may include a material, such as oxide. In some embodiments, the material may include silicon oxide (SiO₂) or the like. The present disclosure is not intended to limit the material of the second oxide layer 140.

In some embodiments, the second oxide layer 140 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electro-chemical plating), electroless plating, or the like. The present disclosure is not intended to limit the methods of forming the second oxide layer 140.

In some embodiments, the second oxide layer 140 may be deposited by a spin-on dielectric coating deposition.

In some embodiments, a material of the second oxide layer 140 is identical to a material of the first oxide layer 130.

In some other embodiments, the method M further includes a step of annealing the first oxide layer 130. The step of annealing the first oxide layer 130 is performed after S103. In some embodiments, the annealing of the first oxide layer 130 is performed between step S103 and step S104. In some embodiments, the step of annealing the first oxide layer 130 may be an annealing process including a heating step and a cooling step after the heating step to cure the first oxide layer 130 with possible defects (for example, grain boundary). This ensures the first oxide layer 130 is formed in the trenches T1 and the trenches T2 without any defect.

In some other embodiments, the method M further includes a step of densifying the second oxide layer 140. The step of densifying the second oxide layer 140 is performed after S104, and the densifying of the second oxide layer 140 is performed after the annealing of the first oxide layer 130. In some embodiments, the step of densifying the second oxide layer 140 may be an annealing process including a heating step and a cooling step after the heating step to cure the second oxide layer 140 with possible defects (for example, grain boundary). This ensures the second oxide layer 140 is formed without any defect.

The step of annealing the first oxide layer 130 has a first process temperature, and the step of densifying the second oxide layer 140 has a second process temperature. The first process temperature and the second process temperature refer to the annealing temperature. In some embodiments, the second process temperature is lower than the first process temperature. The second process temperature is relatively low, so that a problem of array island structure falling can be prevented. Hence, the in-die overlay performance of the semiconductor device 100 can be well improved.

In some other embodiments, the method M further includes a step of annealing both the first oxide layer 130 and the second oxide layer 140. The step of annealing the first oxide layer 130 and the second oxide layer 140 is performed after S104. In some embodiments, the step of annealing both the first oxide layer 130 and the second oxide layer 140 may be regarded as performing the aforementioned densifying of the second oxide layer 140 alone (i.e. without performing the aforementioned annealing the first oxide layer 130). This is because the step of densifying performed after the second deposition process not only densify the second oxide layer 140 but also anneal the first oxide layer 130 substantially.

Reference is made to FIG. 1 and FIG. 7. FIG. 7 is a cross-sectional view of an intermediate stage of manufacturing a semiconductor device 100 in accordance with another embodiment of the present disclosure. As shown in FIG. 7, the method M may further includes a step of removing portions of the first oxide layer 130 and the second oxide layer 140 by a planarization process. In some embodiments, the step of removing the portions of the first oxide layer 130 and the second oxide layer 140 is performed after the step of densifying the second oxide layer 140 (i.e. step S104). More specifically, the step of depositing the first oxide layer 130 (i.e. step S103) and the step of depositing the second oxide layer 140 (i.e. step S104) are performed to overfill the trenches T1 and the trenches T2, in some embodiments. In the step of removing, remaining portions of the first oxide layer 130 and the second oxide layer 140 are co-planar with the patterned hardmask layer 120. As shown in FIG. 7, a surface 130a of the first oxide layer 130 and a surface 140a of the second oxide layer 140 are leveled with the surface 120a of the patterned hardmask layer 120, in some embodiments.

In some embodiments, the planarization process may be performed by a chemical-mechanical planarization (CMP) process.

By performing the method M shown in FIG. 1 of the present disclosure, the semiconductor device 100 with better electrical performance may be formed.

Based on the above discussions, it can be seen that in the semiconductor device and the method of manufacturing the same of the present disclosure, since the step of deposition to fill the trenches with different aspect ratios are split into plural steps, the difficulty of the quality control of the filled material can be lowered down. In the semiconductor device and the method of manufacturing the same of the present disclosure, since the first deposition process is performed by flowable chemical vapor deposition, the trenches in the array area can be fully filled in a proper manner, thereby reducing the probability of generating defects in the dielectric layer, and further prevent the filled dielectric layer from occurring short problem in subsequent process. In the semiconductor device and the method of manufacturing the same of the present disclosure, since the second deposition process is performed by spin-on dielectric coating deposition, since the annealing temperature of the second oxide layer formed by spin-on dielectric coating deposition is relatively low, so that the second deposition process can prevent the problem of the array island structure falling, thereby improving overall electrical performance (for example, in-die overlay performance).

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor device, comprising:
forming a patterned hardmask layer on a surface of a substrate in a periphery area and an array area of the substrate, wherein the patterned hardmask layer has a plurality of hollowed portions;
forming a plurality of trenches on the surface of the substrate in the periphery area and the array area through the hollowed portions of the patterned hardmask layer;
depositing a first oxide layer on inner surfaces of the trenches by a first deposition process, wherein the first deposition process is performed by flowable chemical vapor deposition; and
depositing a second oxide layer on the first oxide layer by a second deposition process, so that the trenches are filled, wherein a material of the first oxide layer and a material of the second oxide layer are identical, wherein the second deposition process is performed by spin-on dielectric coating deposition.

2. The method of claim 1, wherein the first deposition process is performed such that the first oxide layer fully fills the trenches in the array area.

3. The method of claim 2, wherein the first deposition process is performed such that the first oxide layer fully fills the trenches in the array area but does not fully fill the trenches in the periphery area due to the trenches in the array area and the periphery area having different aspect ratios.

4. The method of claim 1, wherein the first oxide layer and the second oxide layer fully fill the trenches in the periphery area.

5. The method of claim 1, wherein the depositing the second oxide layer is performed after the depositing the first oxide layer.

6. The method of claim 1, further comprising annealing the first oxide layer after the depositing the first oxide layer.

7. The method of claim 6, further comprising densifying the second oxide layer after the depositing the second oxide layer.

8. The method of claim 7, wherein a process temperature of the densifying the second oxide layer is lower than a process temperature of the annealing the first oxide layer.

9. The method of claim 7, wherein the densifying the second oxide layer is performed by an annealing process.

10. The method of claim 7, further comprising removing portions of the first oxide layer and the second oxide layer by a planarization process.

11. The method of claim 10, wherein the removing portions of the first oxide layer and the second oxide layer makes remaining portions of the first oxide layer and the second oxide layer be co-planar with the patterned hardmask layer.

12. The method of claim 10, wherein the removing portions of the first oxide layer and the second oxide layer is performed after the densifying the second oxide layer.

13. The method of claim 1, further comprising annealing the first oxide layer and the second oxide layer after the depositing the second oxide layer.

14. A semiconductor device, comprising:
a substrate having a plurality of trenches in a periphery area and an array area of the substrate, wherein an aspect ratio of a width to a depth of the trenches in the periphery area is in a range from 1.25 to 1.5;
a first oxide layer disposed on inner surfaces of the trenches of the substrate; and
a second oxide layer disposed on the first oxide layer, so that the trenches are filled, wherein a material of the first oxide layer and a material of the second oxide layer are identical, and wherein an aspect ratio of the trenches in the array area and the aspect ratio of the trenches in the periphery area are different.

15. The semiconductor device of claim 14, wherein the first oxide layer fully fills the trenches in the array area.

16. The semiconductor device of claim 15, wherein the first oxide layer fully fills the trenches in the array area but does not fill the trenches in the periphery area.

17. The semiconductor device of claim 16, wherein the first oxide layer and the second oxide layer fully fill the trenches in the periphery area.

18. The semiconductor device of claim 14, wherein the aspect ratio of a width to a depth of the trenches in the array area is less than the aspect ratio of the width to the depth of the trenches in the periphery area.
